(19) United States
(12) Patent Application Publication
(10) Pub. No.: US 2020/0284853 A1
(43) Pub. Date: Sep. 10, 2020

(54) Hall Effect Sensor

(71) Applicant: Mattel, Inc., El Segundo, CA (US)

(72) Inventors: Chung Chin Ng, Hong Kong (HK); Man Kwong Yeung, Hong Kong (HK)

(21) Appl. No.: 16/296,552

(22) Filed: Mar. 8, 2019

(51) Int. Cl. G01R 33/00; G01R 33/07

(52) U.S. Cl. CPC G01R 33/0011; G01R 33/07

(57) ABSTRACT

Systems, apparatuses, and methods are described for a Hall effect sensor apparatus comprising a Hall effect integrated circuit and two or more flux concentrating arms. The flux concentrating arms may be located on opposite sides of the Hall effect integrated circuit and may be attached to a circuit board, but need not be attached to the Hall effect integrated circuit. The two flux concentrating arms may extend along two different directions of an axis of the Hall effect integrated circuit. There may be gap between the flux concentrating arms and the Hall effect integrated circuit and/or the circuit board.

### BACKGROUND

Hall effect sensors, circuits which vary voltage based on a magnetic field, may be used in a variety of circumstances to detect the presence of static or dynamic magnetism. Such Hall effect sensors may be used, for example, to determine the revolutions per minute (RPM) of a wheel (e.g., in a vehicle) having a magnet attached to the wheel. Other uses of a Hall effect sensor may include determining the position and/or proximity of a wholly or partially magnetic object. Hall effect sensors may be preferred over other magnetic sensors, such as reed switches, because Hall effect sensors have particularly long lives and may allow for nuanced measurement of magnetic fields.

Modern Hall effect sensors are quite small and, while powerful, often require that magnetic fields be very close, be particularly oriented, and/or very strong for detection. But in many circumstances, placing a magnetic object closer to the Hall effect sensor may be undesirable at least because it may risk damaging the Hall effect sensor (e.g., if the object is a spinning disk). The orientation of a magnetic field may be difficult to ensure in circumstances where an object may easily move (e.g., such that the magnetic field is prone to rapid change). Also, a magnetic field may be difficult to measure if, for example, the desired object to be measured is a particularly weak permanent magnet. Previous solutions to such problems have been expensive, fragile, and/or reliant on a magnetic environment being controlled.

### SUMMARY

The following summary presents a simplified summary of certain features. The summary is not an extensive overview and is not intended to identify key or critical elements.

Systems, apparatuses, and methods are described for a Hall effect sensor comprising a Hall effect integrated circuit (IC) and two or more rectangular flux guidance plates. The Hall effect IC may be any conventional Hall effect sensor such as, e.g., the DRV5013 Hall effect sensor sold by Texas Instruments of Dallas, Tex. Above the Hall effect IC, a first rectangular flux guidance plate may extend in a first direction such that the first rectangular flux guidance plate is at least partially on top of the Hall effect IC. Below the Hall effect IC, a second rectangular flux guidance late may extend in a second direction, opposite the first direction, such that the second rectangular flux guidance plate is at least partially below the Hall effect IC. The Hall effect IC, first rectangular flux guidance plate, and second rectangular flux guidance plate may be attached to a printed circuit board, which may comprise wiring such that voltage and current may be applied to the Hall effect IC. The printed circuit board may comprise one or more attachment points for connecting the Hall effect sensor to an object, such as a toy.

These and other features and advantages are described in greater detail below.

### BRIEF DESCRIPTION OF THE DRAWINGS

Some features are shown by way of example, and not by limitation, in the accompanying drawings. In the drawings, like numerals reference similar elements.

FIG. 1 shows a side view of a Hall effect IC between a first arm and a second arm.

FIG. 2 shows a Hall effect sensor assembly comprising rectangular magnetic guidance plates.

FIG. 3 shows a region of magnetic sensitivity of the Hall effect sensor assembly.

FIG. 4 shows a cutaway view of the Hall effect sensor assembly.

### DETAILED DESCRIPTION

The accompanying drawings, which form a part hereof, show examples of the disclosure. It is to be understood that the examples shown in the drawings and/or discussed herein are non-exclusive and that there are other examples of how the disclosure may be practiced.

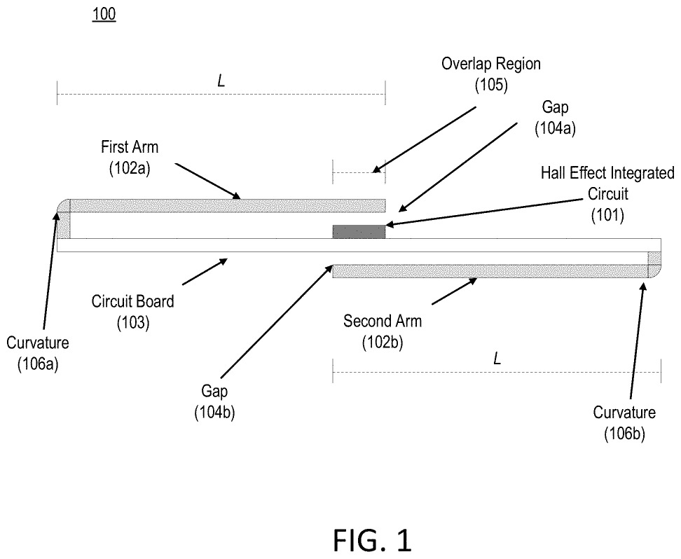

FIG. 1 shows a side view of a Hall effect sensor apparatus 100 comprising a Hall effect IC 101 between a first arm 102a and a second arm 102b. The Hall effect IC 101 shown in FIG. 1 is an example, and other integrated circuits sensitive to the Hall effect may be used. The Hall effect IC 101 is located on a circuit board 103. At opposite ends of the circuit board 103, a first arm 102a and a second arm 102b are attached, which extend by a length L to overlap above and below the Hall effect IC 101 in an area designated as an overlap region 105. The first arm 102a and the second arm 102b need not contact the Hall effect IC 101; rather, a gap 104a and a gap 104b separate the Hall effect IC 101 from the first arm 102a and the second arm 102b, respectively. The gap 104a and/or the gap 104b may comprise air, all or portions of the circuit board 103, glue, or the like. Thus, for example, while FIG. 1 shows a gap 104b including air, the second arm 102b may physically contact the circuit board 103, such that the gap 104b comprises the thickness of the circuit board 103.

The Hall effect IC 101 may be configured to measure magnetism along one or more axes. For example, the Hall effect IC 101 may be one-axis, two-axis, or three-axis, meaning that it may detect magnetism along a single or a plurality of axes. If the Hall effect IC 101 is configured to detect magnetism along a plurality of axes, it may be biased to detect magnetism more strongly along a first axis as compared to a second and/or third axis. The first arm 102a and/or the second arm 102b may be aligned along one or more of these axes.

The circuit board 103 may be any element configured to hold the Hall effect IC 101, the first aim 102a, and/or the second arm 102b. The circuit board 103 may comprise a non-conductive substrate and/or a conductive substrate. For example, one or more first portions the circuit board 103 may comprise a non-conductive but sturdy substance, whereas one or more second portions of the printed circuit board may be conductive and may couple the Hall effect IC 101 to a power source.

The first arm 102a and the second arm 102b may be magnetic guidance plates on opposite sides of the circuit board 103 which act as flux concentrators with respect to the Hall effect IC. The first arm 102a and the second arm 102b may be metal, made of a metallic substance, and/or may have properties which direct magnetism towards the Hall effect IC 101. The first arm 102a and/or the second arm 102b may be configured to react to the presence of magnetism that need not be present at the Hall effect IC 101. For example, the presence of magnetism at the first arm 102a may cause magnetism in the first arm 102a itself, which may cause corresponding magnetism at the Hall effect IC 101. The first arm 102a and/or the second arm 102b may thereby extend the magnetic sensitivity of the Hall effect IC 101 in two directions (e.g., a first direction and a second direction, wherein the second direction is opposite the second direction) while simultaneously limiting the sensitivity of the Hall effect IC 101 in other directions. Additional rectangular magnetic guidance plates (not shown) may be implemented to add sensitivity of the Hall effect IC 101 to other axes.

The first arm 102a may have a curvature 106a, and the second arm 102b may have a curvature 106b, such that the arms may be curve towards and contact the circuit board 103. The first arm 102a and/or the second arm 102b may otherwise be substantially rectangular. This contact occurs near the ends of the circuit board 103 such that the first arm 102a and the second arm 102b need not physically contact the Hall effect IC 101. Connection of the first arm 102a and/or the second arm 102b may be made by, e.g., inserting the first arm 102a and/or the second arm 102b into a slot of the circuit board 103 and/or gluing the first arm 102a and/or the second arm 102b in place. The first arm 102a and the second arm 102b may both have a length L extending in different directions away from the Hall effect IC 101, and both may cover the top and/or bottom of the Hall effect IC in the overlap region 105. For example, as shown in FIG. 1, the first arm 102a may be above the Hall effect IC 101 and extend leftward from the Hall effect IC 101, whereas the second arm 102b may be below the Hall effect IC 101 and may extend rightward from the Hall effect IC 101. The first arm 102a and/or the second arm 102b may be additionally and/or alternatively referred to as flux concentrators.

The first arm 102a and/or the second arm 102b may be configured with respect to an axis. The Hall effect IC 101 may be particularly sensitive in a particular axis (e.g., to the left and right of FIG. 1), and the first arm 102a and/or the second arm 102b may extend in opposite directions of this axis. Additionally or alternatively, the first arm 102a and/or the second arm 102b may be configured to extend in opposite directions along an axis other than that which the Hall effect IC 101 is sensitive.

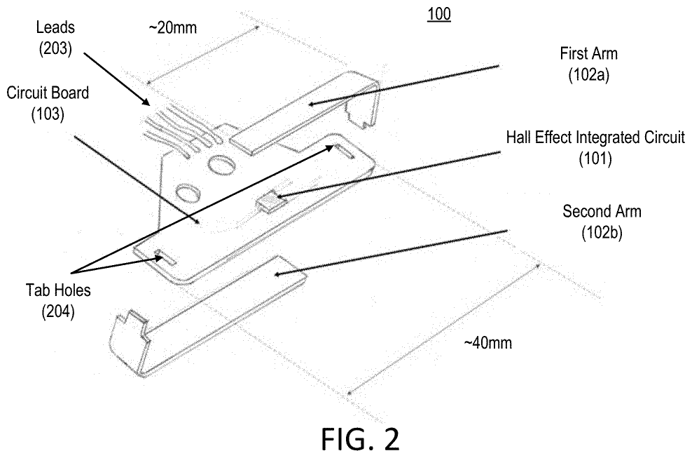

FIG. 2 shows a diagonal perspective of the Hall effect sensor apparatus 100 comprising the Hall effect IC 101, the first arm 102a, and the second arm 102b, as combined on the circuit board 103. The circuit board 103 may comprise leads 203 connecting to the Hall effect IC 101 and one or more tab holes 204 for connecting the first arm 102a and/or the second arm 102b to the circuit board 103.

The first arm 102a and/or the second arm 102b may be configured to attach above and/or below the Hall effect IC 101. The first arm 102a and/or the second arm 102b may be curved or otherwise shaped to attach to the circuit board 103 using tabs and/or other fasteners. For example, the first arm 102a and/or the second arm 102b shown in FIG. 2 may be attached to the printed circuit board using tabs inserted into the tab holes 204 of the circuit board 103, but need not physically contact the Hall effect IC 101. Not physically connecting to the Hall effect IC 101 may avoid adding additional substances (e.g., adhesive) to the Hall effect IC, as such substances may undesirably interfere with the sensitivity of the Hall effect IC 101.

Use of two or more magnetic guidance plates, such as the first arm 102a and the second arm 102b, may advantageously avoid shielding effects present with larger and/or longer metal or metallic flux guides. For example, removing the second arm 102b and lengthening the first arm 102a to the entire length of the circuit board 103 may undesirably cause the first arm 102a to act as a shield for magnetism, thereby potentially preventing magnetism from reaching the Hall effect IC. As such, the first arm 102a and the second arm 102b need not exhibit the same or similar responses to magnetism imposed on and/or near the Hall effect sensor apparatus 100.

The circuit board 103 shown in FIG. 2 may have a shape that is longer in one direction than another. For example, as shown in FIG. 2, the circuit board 103 may have a length (e.g., 40 mm) that is the combined length of the first arm 102a and the second arm 102b (e.g., each being 20 mm, or 40 mm total). The Hall effect IC may be, for example, 3 mm×3 mm. The small size of the circuit board 103 may advantageously allow it and the Hall effect IC 101 to be protected by the first arm 102a and/or the second arm 102b. For example, the first arm 102a and/or the second arm 102b may be reinforced or otherwise designed with a thickness such that the Hall effect IC 101 is protected from damage.

The leads 203 may be configured to carry power to the Hall effect IC, and/or may be configured to transmit voltage corresponding to the Hall effect. The leads 203 may comprise wire, such as copper wire. The leads 203 may be configured such that the overall resistivity of the leads 203 is minimized.

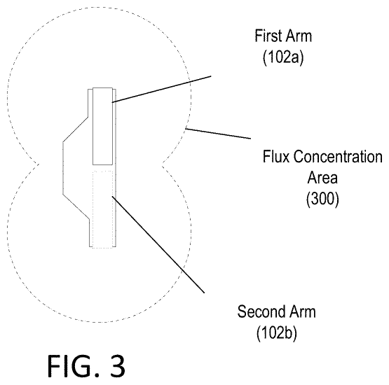

FIG. 3 shows a flux concentration area 300 of the Hall effect sensor apparatus 100. The Hall effect sensor apparatus 100 may be configured to detect magnetism on an axis. For example, as shown in FIG. 3, the vertical axis corresponds to two large regions of magnetic sensitivity (corresponding to the length of the first arm 102a and/or the second arm 102b), whereas the horizontal axis has less magnetic sensitivity. The Hall effect sensor apparatus 100 may therefore be configured to detect magnetism along a first axis, but not a second axis. Moreover, because the first arm 102a may be on top of the circuit board 103, and because the second arm 102b may be below the circuit board 103, magnetism above the circuit board 103 may be more readily detected by the first arm 102a, whereas magnetism below the circuit board 103 may be more readily detected by the second arm 102b. The first arm 102a and the second arm 102b, by being located on opposite directions of an axis and on opposite sides of the circuit board 103, may thereby advantageously expand the magnetic sensitivity of the Hall effect IC 101 far beyond its typical range.

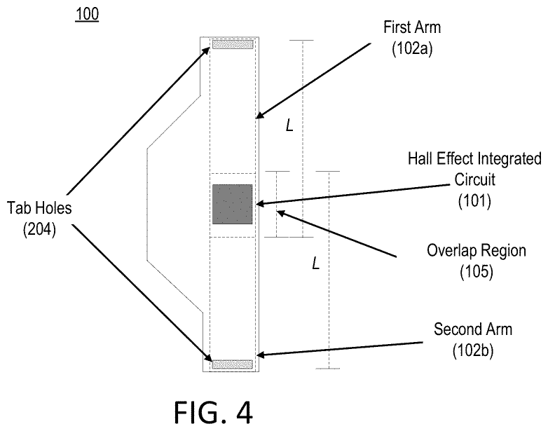

FIG. 4 shows the Hall effect sensor apparatus 100 with the first arm 102a and the second arm 102b made transparent, revealing the tab holes 204, the Hall effect IC 101, and the overlap region 105. As may be seen from the perspective in FIG. 4, the overlap region 105 comprises a portion of the length L of each of the first arm 102a and the second arm 102b. For example, the overlap region 105 may be one-third of the length L of the first arm 102a.

Although examples are described above, features and/or steps of those examples may be combined, divided, omitted, rearranged, revised, and/or augmented in any desired manner. Various alterations, modifications, and improvements will readily occur to those skilled in the art. Such alterations, modifications, and improvements are intended to be part of this description, though not expressly stated herein, and are intended to be within the spirit and scope of the disclosure. Accordingly, the foregoing description is by way of example only, and is not limiting.

1. A Hall effect sensor apparatus comprising:
a Hall effect integrated circuit configured to detect magnetism;
a first flux concentrating arm above the Hall effect integrated circuit; and
a second flux concentrating arm below the Hall effect integrated circuit, wherein the first flux concentrating arm and the second flux concentrating arm overlap the Hall effect integrated circuit without physically contacting the Hall effect integrated circuit, and wherein the first flux concentrating arm and the second flux concentrating arm extend away from the Hall effect integrated circuit along opposite directions of an axis.

2. The Hall effect sensor apparatus of claim 1, wherein the first flux concentrating arm and the second flux concentrating arm have a length of 20 mm.

3. The Hall effect sensor apparatus of claim 2, wherein a length of the Hall effect sensor apparatus is 40 mm.

4. The Hall effect sensor apparatus of claim 1, wherein the first flux concentrating arm and the second flux concentrating arm are substantially rectangular.

5. The Hall effect sensor apparatus of claim 1, wherein the first flux concentrating arm and the second flux concentrating arm are made of a metallic substance.

6. The Hall effect sensor apparatus of claim 1, further comprising:
a non-conductive substrate between the first flux concentrating arm and the second flux concentrating arm, wherein the Hall effect integrated circuit is mounted on the non-conductive substrate.

7. The Hall effect sensor apparatus of claim 6, wherein the non-conductive substrate is a printed circuit board.

8. The Hall effect sensor apparatus of claim 6, wherein the first flux concentrating arm and the second flux concentrating arm are physically connected to the non-conductive substrate.

9. The Hall effect sensor apparatus of claim 6, further comprising:
a gap between the second flux concentrating arm and the non-conductive substrate.

10. The Hall effect sensor apparatus of claim 1, wherein the first flux concentrating arm and the second flux concentrating arm have an equal length.

11. The Hall effect sensor apparatus of claim 1, further comprising:
a gap between the first flux concentrating arm and the Hall effect integrated circuit.

12. The Hall effect sensor apparatus of claim 1, further comprising:
a gap between the second flux concentrating arm and the Hall effect integrated circuit.

13. The Hall effect sensor apparatus of claim 1, wherein the Hall effect integrated circuit is more sensitive along a direction corresponding to the axis.

14. The Hall effect sensor apparatus of claim 1, wherein the Hall effect sensor apparatus is configured to detect magnetism along the axis.

15. A Hall effect sensor apparatus comprising:
a Hall effect integrated circuit configured to detect magnetism;
a first flux concentrating arm above the Hall effect integrated circuit and extending in a first direction along an axis;
a second flux concentrating arm below the Hall effect integrated circuit and extending in a second direction along the axis, wherein the second direction is opposite the first direction; and
a circuit board comprising the Hall effect integrated circuit, wherein the circuit board is configured to attach the first flux concentrating arm and the second flux concentrating arm on opposite sides of the circuit board.

16. The Hall effect sensor apparatus of claim 15, wherein a first length of the first flux concentrating arm is the same as a second length of the second flux concentrating arm.

17. The Hall effect sensor apparatus of claim 15, wherein the first flux concentrating arm and the second flux concentrating arm are configured to not touch the Hall effect integrated circuit.

18. A system comprising:
a magnetic element configured to cause magnetism, and
a Hall effect sensor apparatus comprising:
a Hall effect integrated circuit configured to detect the magnetism;
a first flux concentrating arm above the Hall effect integrated circuit; and
a second flux concentrating arm below the Hall effect integrated circuit, wherein the first flux concentrating arm and the second flux concentrating arm overlap the Hall effect integrated circuit without physically contacting the Hall effect integrated circuit, and wherein the first flux concentrating arm and the second flux concentrating arm extend away from the Hall effect integrated circuit along opposite directions of an axis.

19. The system of claim 18, wherein the first flux concentrating arm and the second flux concentrating arm have a length of 20 mm.

20. The system of claim 18, wherein the first flux concentrating arm and the second flux concentrating arm are substantially rectangular.
